(19) United States
(12) Patent Application Publication
(10) Pub. No.: US 2026/0223642 A1
(43) Pub. Date: Jul. 30, 2026

(54) SUBSTRATE SUPPORT ASSEMBLY, SUBSTRATE PROCESSING APPARATUS, AND SUBSTRATE PROCESSING METHOD

(71) Applicant: Tokyo Electron Limited, Tokyo (JP)

(72) Inventors: Akira NAGAYAMA, Miyagi (JP); Atsushi KAWABATA, Miyagi (JP)

(73) Assignee: Tokyo Electron Limited, Tokyo (JP)

(21) Appl. No.: 19/629,337

(22) Filed: Mar. 26, 2026

Related U.S. Application Data
(63) Continuation of application No. PCT/JP2024/033939, filed on Sep. 24, 2024.

(30) Foreign Application Priority Data
Oct. 3, 2023 (JP) 2023-171801

(51) Int. Cl. H10P 72/76; H01J 37/32; H10P 72/00

(52) U.S. Cl. CPC H10P 72/7624; H01J 37/32724; H10P 72/0432; H01J 2237/002

(57) ABSTRACT

Provided is a substrate support assembly. A base of the substrate support assembly includes a flow path. The first container is configured to change a first capacity therein such that the heat transfer medium is supplied to the flow path via the at least one first pipe by a decrease in the first capacity. A second container is configured to change a second capacity therein such that a gas is supplied to the flow path by a decrease in the second capacity. The first container and the second container are configured such that a decrease in one of the first capacity and the second capacity causes an increase in the other. The heat transfer medium supply further includes at least one third pipe and a valve.

### CROSS-REFERENCE TO RELATED APPLICATIONS

This application is a continuation application of PCT Application No. PCT/JP2024/033939, filed on Sep. 24, 2024, which claims the benefit of priority from Japanese Patent Application No. 2023-171801, filed on Oct. 3, 2023. The entire contents of the above listed PCT and priority applications are incorporated herein by reference.

### BACKGROUND

### Field

Exemplary embodiments of the present disclosure relate to a substrate support assembly, a substrate processing apparatus, and a substrate processing method.

A plasma processing apparatus is used in plasma processing of a substrate. A plasma processing apparatus disclosed in Japanese Unexamined Patent Publication includes a chamber and a suction device. The suction device suctions the substrate. A refrigerant flow path is formed inside the suction device. A refrigerant is supplied to the refrigerant flow path from a refrigerant supply port. The refrigerant supplied to the refrigerant flow path is discharged from a refrigerant discharge port.

### SUMMARY

In one exemplary embodiment, a substrate support assembly includes a base, a substrate support on the base, and a heat transfer medium supply. The base includes a flow path. The heat transfer medium supply is connected to the flow path. The heat transfer medium supply includes a first container, a first pipe, a second container, a second pipe, at least one third pipe and a valve. The first container is configured to store the heat transfer medium. At least one first pipe is connected between a first end of the flow path and the first container. The second container is configured to store a gas. The second pipe is connected between a second end of the flow path and the second container. The first container is configured to change a first capacity therein such that the heat transfer medium is supplied to the flow path via the at least one first pipe by a decrease in the first capacity. The second container is configured to change a second capacity therein such that the gas is supplied to the flow path via the at least one second pipe by a decrease in the second capacity. The first container and the second container are configured such that a decrease in one of the first capacity and the second capacity causes an increase in the an other of the first capacity and the second capacity. The valve is connected between the first container and the second container via the at least one third pipe.

### BRIEF DESCRIPTION OF THE DRAWINGS

FIG. 1 is a diagram showing a configuration example of a plasma processing system.

FIG. 2 is a diagram showing a configuration example of a capacitively coupled plasma processing apparatus.

FIG. 3 is a diagram schematically showing a substrate support assembly according to one exemplary embodiment.

FIG. 4 is a cross-sectional view of a partition wall according to one exemplary embodiment.

FIG. 5 is a diagram schematically showing a substrate support assembly according to another exemplary embodiment.

FIG. 6 is a flowchart showing a substrate processing method according to one exemplary embodiment.

### DETAILED DESCRIPTION

Hereinafter, various exemplary embodiments will be described in detail with reference to the accompanying drawings. In the drawings, the same or equivalent portions are denoted by the same reference symbols.

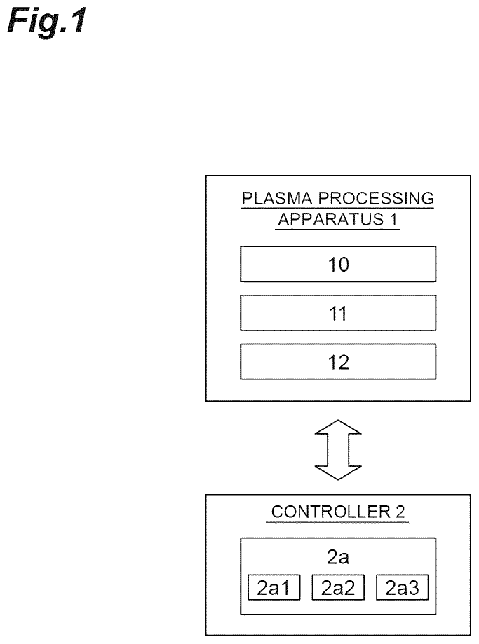

FIG. 1 shows a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support assembly 11, and a plasma generator 12. The plasma processing chamber 10 includes a plasma processing space. The plasma processing chamber 10 further has at least one gas supply port in order to supply at least one process gas into the plasma processing space and at least one gas exhaust port for exhausting gases from the plasma processing space. The gas supply port is connected to a gas supply 20 described later and the gas exhaust port is connected to an exhaust system 40 described later. The substrate support assembly 11 is disposed in the plasma processing space, and includes a substrate support surface for supporting a substrate.

The plasma generator 12 is configured to generate plasma from at least one process gas supplied into the plasma processing space. The plasma formed in the plasma processing space may be capacitively coupled plasma (CCP), inductively coupled plasma (ICP), electron-cyclotron-resonance (ECR) plasma, helicon wave plasma (HWP), or surface wave plasma (SWP). Further, various types of plasma generators including an alternating current (AC) plasma generator and a direct current (DC) plasma generator may be used. In one embodiment, an AC signal (AC power) used in the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions causing the plasma processing apparatus 1 to perform various steps described in the present disclosure. The controller 2 may be configured to control individual elements of the plasma processing apparatus 1 such that these elements execute the various steps. In one embodiment, the functions of the controller 2 may be partially or entirely incorporated into the plasma processing apparatus 1. The controller 2 may include a processor 2a1, a storage 2a2, and a communication interface 2a3. The controller 2 is implemented by, for example, a computer 2a. The processor 2a1 may be configured to read a program from the storage 2a2, and then perform various control operations by executing the program. This program may be stored in the storage 2a2 in advance, or may be acquired from a medium as needed. The acquired program is stored in the storage 2a2, and then the processor 2a1 reads the program from the storage 2a2 for execution. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or combinations thereof. The communication interface 2a3 may communicate with the plasma processing apparatus 1 via the communication line such as a local area network (LAN).

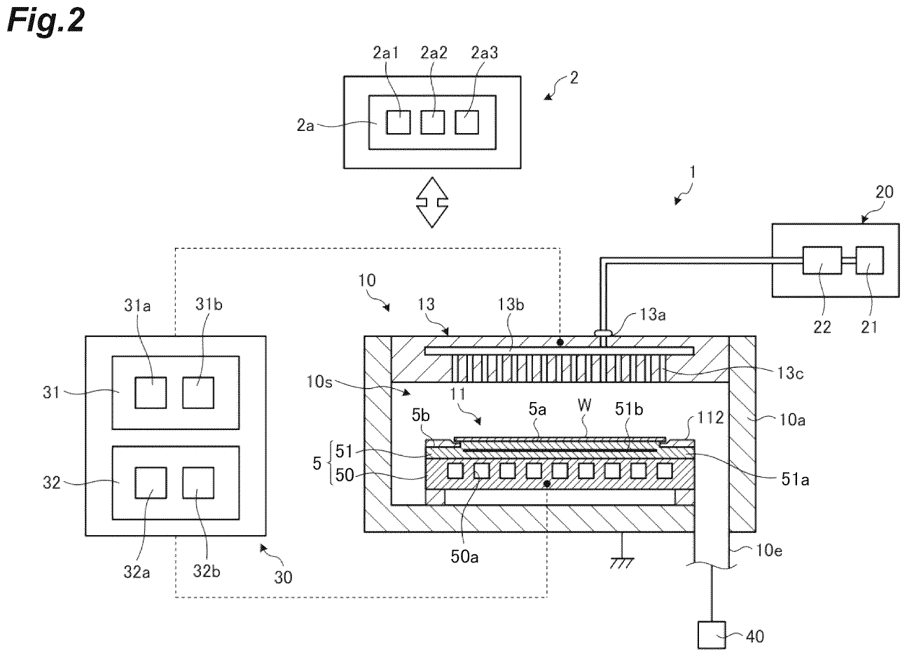

Hereinafter, a configuration example of a capacitively coupled plasma processing apparatus, which is an example of the plasma processing apparatus 1, will be described. FIG. 2 shows the configuration example of the capacitively coupled plasma processing apparatus.

The capacitively coupled plasma processing apparatus 1 includes a plasma processing chamber 10, a gas supply 20, a power supply 30, and an exhaust system 40. Further, the plasma processing apparatus 1 includes a substrate support assembly 11 and a gas introducer. The gas introducer is configured to introduce at least one process gas into the plasma processing chamber 10. The gas introducer includes a showerhead 13. The substrate support assembly 11 is disposed in the plasma processing chamber 10. The showerhead 13 is disposed above the substrate support assembly 11. In one embodiment, the showerhead 13 constitutes at least a part of a ceiling of the plasma processing chamber 10. The plasma processing chamber 10 includes a plasma processing space 10s defined by the showerhead 13, a side wall 10a of the plasma processing chamber 10, and the substrate support assembly 11. The plasma processing chamber 10 is grounded. The showerhead 13 and the substrate support assembly 11 are electrically insulated from a housing of the plasma processing chamber 10.

The substrate support assembly 11 includes a main body 5 and a ring assembly 112. The main body 5 includes a central region 5a for supporting a substrate W and an annular region 5b for supporting the ring assembly 112. A wafer is an example of the substrate W. The annular region 5b of the main body 5 surrounds the central region 5a of the main body 5 in plan view. The substrate W is disposed on the central region 5a of the main body 5, and the ring assembly 112 is disposed on the annular region 5b of the main body 5 to surround the substrate W on the central region 5a of the main body 5. Therefore, the central region 5a is also called a substrate support surface for supporting the substrate W, while the annular region 5b is also called a ring support surface for supporting the ring assembly 112.

In one embodiment, the main body 5 includes a base 50 and a substrate support 51. The substrate support 51 is, for example, an electrostatic chuck. The base 50 includes a conductive member. The conductive member of the base 50 can function as a lower electrode. The substrate support 51 is disposed on the base 50. The substrate support 51 includes a ceramic member 51a and an electrostatic electrode 51b disposed in the ceramic member 51a. The ceramic member 51a includes the central region 5a. In one embodiment, the ceramic member 51a also includes the annular region 5b. Other members surrounding the substrate support 51, such as an annular electrostatic chuck or an annular insulating member, may include the annular region 5b. In this case, the ring assembly 112 may be disposed on the annular electrostatic chuck, or may be the annular insulating member, or may be disposed on both the substrate support 51 and the annular insulating member. At least one RF/DC electrode coupled to an RF power supply 31 and/or a DC power supply 32 described later may be disposed in the ceramic member 51a. In this case, at least one RF/DC electrode functions as a lower electrode. In a case where a bias RF signal and/or a DC signal described later are supplied to at least one RF/DC electrode, the RF/DC electrode is also called a bias electrode. The conductive member of the base 50 and at least one RF/DC electrode may each function as a lower electrode. Further, the electrostatic electrode 51b may function as a lower electrode. Accordingly, the substrate support assembly 11 includes at least one lower electrode.

The ring assembly 112 includes one or more annular members. In one embodiment, one or more annular members include one or more edge rings and at least one cover ring. The edge ring is made of a conductive or insulating material, whereas the cover ring is made of an insulating material.

The showerhead 13 is configured to introduce at least one process gas from the gas supply 20 into the plasma processing space 10s. The showerhead 13 includes at least one gas supply port 13a, at least one gas diffusion space 13b, and a plurality of gas introduction ports 13c. The process gas supplied to the gas supply port 13a passes through the gas diffusion space 13b and is then introduced into the plasma processing space 10s from the plurality of gas introduction ports 13c. Further, the showerhead 13 includes at least one upper electrode. The gas introducer may include one or more side gas injectors (SGI) provided at one or more openings formed in the side wall 10a, in addition to the showerhead 13.

The gas supply 20 may include at least one gas source 21 and at least one flow rate controller 22. In one embodiment, the gas supply 20 is configured to supply at least one process gas from the corresponding gas source 21 through the corresponding flow rate controller 22 into the showerhead 13. Each flow rate controller 22 may be, for example, a mass flow controller or a pressure-controlled flow rate controller. Further, the gas supply 20 may include at least one flow rate modulation device that can modulate or pulse the flow rate of at least one process gas.

The power supply 30 includes the RF power supply 31 coupled to the plasma processing chamber 10 through at least one impedance matching circuit. The RF power supply 31 is configured to supply at least one RF signal (RF power) to at least one lower electrode and/or at least one upper electrode. As a result, a plasma is formed from at least one process gas supplied into the plasma processing space 10s. Therefore, the RF power supply 31 can function as at least part of the plasma generator 12. Further, by supplying a bias RF signal to at least one lower electrode, a bias potential is generated on the substrate W, and an ion component in the formed plasma can be attracted to the substrate W.

In one embodiment, the RF power supply 31 includes a first RF generator 31a and a second RF generator 31b. The first RF generator 31a is coupled to at least one lower electrode and/or at least one upper electrode through at least one impedance matching circuit, and is configured to generate a source RF signal (source RF power) for generating the plasma. In one embodiment, the source RF signal has a frequency in a range of 10 MHz to 150 MHz. In one embodiment, the first RF generator 31a may be configured to generate a plurality of source RF signals having different frequencies. The one or more generated source RF signals are supplied to at least one lower electrode and/or at least one upper electrode.

The second RF generator 31b is coupled to at least one lower electrode through at least one impedance matching circuit, and is configured to generate a bias RF signal (bias RF power). The frequency of the bias RF signal is the same as or different from the frequency of the source RF signal. In one embodiment, the bias RF signal has a frequency less than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The one or more generated bias RF signals are supplied to at least one lower electrode. Further, in various embodiments, at least one of the source RF signal and the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is connected to at least one lower electrode, and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform that is rectangular, trapezoidal, triangular, or a combination thereof. In one embodiment, a waveform generator for generating the sequence of voltage pulses from the DC signal is disposed between the first DC generator 32a and at least one lower electrode. Therefore, the first DC generator 32a and the waveform generator function as a voltage pulse generator. In a case where the second DC generator 32b and the waveform generator function as a voltage pulse generator, the voltage pulse generator is connected to at least one upper electrode. The voltage pulse may have positive polarity, or may be negative polarity. The sequence of voltage pulses may also include one or more positive-polarity voltage pulses and one or more negative-polarity voltage pulses within one cycle. The first and second DC generators 32a and 32b may be disposed in addition to the RF power supply 31, or the first DC generator 32a may be disposed instead of the second RF generator 31b.

The exhaust system 40 may be connected to, for example, a gas exhaust port 10e provided in the bottom portion of the plasma processing chamber 10. The exhaust system 40 may include a pressure adjustment valve and a vacuum pump. The pressure adjustment valve adjusts the pressure in the plasma processing space 10s. The vacuum pump may be a turbo-molecular pump, a dry pump, or a combination thereof.

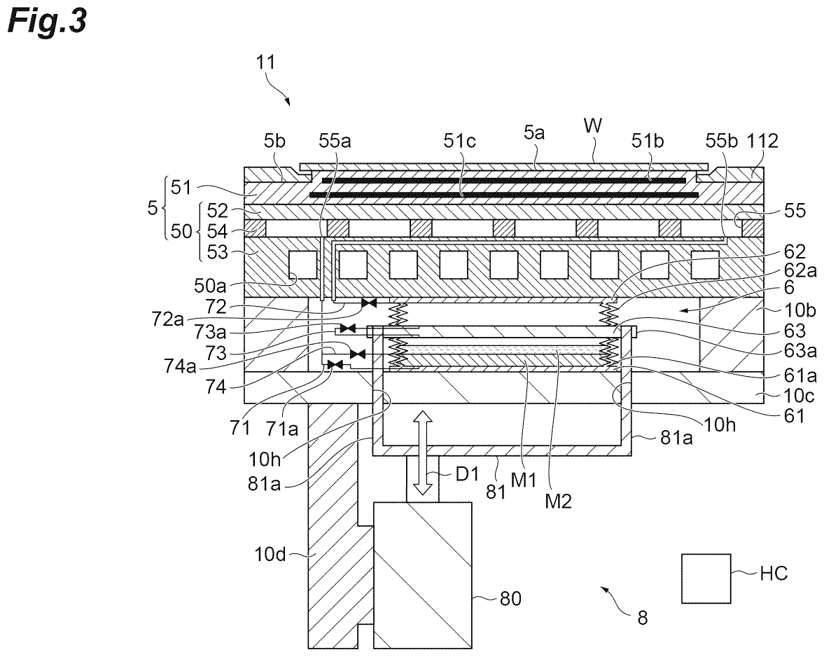

FIG. 3 is a diagram schematically showing the substrate support assembly according to one exemplary embodiment. As described above, the substrate support assembly 11 includes the main body 5. The main body 5 includes the base 50 and the substrate support 51 on the base 50. The substrate support 51 is disposed on the base 50. In one embodiment, the base 50 may be supported on a base material 10c via an insulating member 10b. In the example shown in FIG. 3, the main body 5 is supported by the insulating member 10b in the chamber 10. The insulating member 10b is disposed on the base material 10c. The base material 10c may constitute a bottom wall of the chamber 10.

In one embodiment, the substrate support assembly 11 may further include at least one heater 51c. The heater 51c is disposed in the substrate support 51. The heater 51c is disposed, for example, in a ceramic member 51a of the substrate support 51. The heater 51c is positioned below an electrostatic electrode 51b. The heater 51c generates heat by receiving power supplied from a power supply (not shown) controlled by a heater controller HC. The substrate support assembly 11 may include a temperature control module configured to adjust at least one of the substrate support 51, the ring assembly 112, and the substrate W to a target temperature. In addition, the substrate support assembly 11 may include a heat transfer gas supply configured to supply a heat transfer gas to a gap between a back surface of the substrate W and the central region 5a.

The base 50 includes a flow path 55 and a flow path 50a. In one embodiment, the flow path 55 is a flow path for at least one heat transfer medium, and the flow path 50a is a flow path for another heat transfer medium different from at least one heat transfer medium. The flow path 50a and the flow path 55 may be provided in the base 50. The flow path 50a and the flow path 55 may be independent of each other.

In one embodiment, at least one heat transfer medium may be a plurality of heat transfer media. The plurality of heat transfer media include a first heat transfer medium M1 (heat transfer medium) and a second heat transfer medium M2. The first heat transfer medium M1 has a first specific gravity. The second heat transfer medium M2 has a second specific gravity. The second specific gravity is smaller than the first specific gravity. The first heat transfer medium M1 has a first thermal conductivity. The second heat transfer medium M2 has a second thermal conductivity. The first thermal conductivity may be greater than the second thermal conductivity.

In one embodiment, the first heat transfer medium M1 may be a liquid metal. The liquid metal may be a metal or a eutectic alloy having a melting point of −10° C. or lower and a thermal conductivity of 5 W/mK or more at normal pressure (atmospheric pressure). The melting point of the liquid metal at normal pressure (atmospheric pressure) may be −15° C. or lower. The liquid metal is, for example, a Ga-In-Sn alloy. In the Ga-In-Sn alloy, a concentration of Ga may be 62% by mass, a concentration of In may be 25% by mass, and a concentration of Sn may be 13% by mass. The Ga-In-Sn alloy may be, for example, Galinstan (registered trademark). In one embodiment, the first heat transfer medium M1 may be a silicone oil, an anhydrous alcohol, ethylene glycol, or a fluorine-based refrigerant liquid. In one example, the first heat transfer medium M1 may be water.

In one embodiment, the second heat transfer medium M2 may be another liquid different from the liquid metal. The other liquid may be a liquid that does not chemically react with the liquid metal and does not contain moisture. Further, the other liquid may have a melting point lower than the melting point of the liquid metal. The other liquid is, for example, a silicone oil, an anhydrous alcohol, ethylene glycol, or a fluorine-based refrigerant liquid. In one example, the second heat transfer medium M2 may be water. The first heat transfer medium M1 and the second heat transfer medium M2 may be liquids that are incompatible with each other.

In one embodiment, the base 50 may include a first base 52, a second base 53, and a support member 54. The first base 52 supports the substrate support 51 disposed thereon. The second base 53 is disposed below the first base 52 and includes the flow path 50a inside. The support member 54 is interposed between the first base 52 and the second base 53 to support the first base 52. The support member 54 defines the flow path 55 between the first base 52 and the second base 53. In one example, the flow path 55 extends between the flow path 50a and the substrate support 51.

In one embodiment, the thermal conductivity of the material of the support member 54 may be lower than the thermal conductivity of the material of the base 50. The thermal conductivity of the material of the support member 54 may be 1 W/mK or less. The support member 54 includes for example, at least one material selected from the group consisting of a resin material, ceramic, and a composite material. The support member 54 may include a fluororesin. The support member 54 may include at least one material selected from the group consisting of polytetrafluoroethylene, polyether ether ketone, and porous ceramic. The support member 54 may include a composite material. The composite material is a material made by combining two or more different materials. For example, the composite material is a material made by combining two or more materials selected from the group consisting of resin, metal, glass, and carbon.

The other heat transfer medium different from at least one heat transfer medium may be, for example, a refrigerant such as brine or gas. The substrate support assembly 11 may further include a chiller unit. The chiller unit may be connected to the flow path 50a to supply the other heat transfer medium to the flow path 50a.

The substrate support assembly 11 includes a heat transfer medium supply 6. The heat transfer medium supply 6 is connected to the flow path 55 and is configured to supply the heat transfer medium selected from among the plurality of heat transfer media described above to the flow path 55. The above-described temperature control module may include the heat transfer medium supply 6, the heater 51c, the heater controller HC, the flow path 55, the flow path 50a, the chiller unit, or a combination thereof.

In one embodiment, the heat transfer medium supply 6 may be disposed between the base material 10c and the base 50. The heat transfer medium supply 6 may be disposed inside the chamber 10. However, the heat transfer medium supply 6 may be disposed outside the chamber 10. The heat transfer medium supply 6 is insulated from the chamber 10.

The heat transfer medium supply 6 includes at least one first pipe 71, a first container 61, at least one second pipe 72, a second container 62, at least one third pipe 73, and a valve 73a (third valve). In one embodiment, the heat transfer medium supply 6 may further include a valve 71a (first valve), a valve 72a (second valve), at least one fourth pipe 74, and a valve 74a (fourth valve).

At least one first pipe 71 is connected between the first end 55a of the flow path 55 and the first container 61. In one embodiment, the valve 71a is connected between the first end 55a and the first container 61 via at least one first pipe 71. In the example shown in FIG. 3, the heat transfer medium supply 6 includes a plurality of first pipes 71. One of the plurality of first pipes 71 connects the first end 55a and the valve 71a to each other, and another one of the plurality of first pipes 71 connects the valve 71a and the first container 61 to each other. The first container 61 may be provided below the second container 62 as will be described later. A position at which the other one of the plurality of first pipes 71 is connected to the first container 61 may be, for example, a bottom portion of the first container 61.

At least one second pipe 72 is connected between the second end 55b of the flow path 55 and the second container 62. The second end 55b is an end of the flow path 55 on a side opposite to the first end 55a. In one embodiment, the valve 72a is connected between the second end 55b and the second container 62 via at least one second pipe 72. In the example shown in FIG. 3, the heat transfer medium supply 6 includes a plurality of second pipes 72. One of the plurality of second pipes 72 connects the second end 55b and the valve 72a to each other, and another one of the plurality of second pipes 72 connects the valve 72a and the second container 62 to each other. A position at which the other one of the plurality of second pipes 72 is connected to the second container 62 may be, for example, a ceiling (or an upper wall) of the second container 62.

At least one third pipe 73 is connected between the first container 61 and the second container 62. The valve 73a is connected between the first container 61 and the second container 62 via at least one third pipe 73. In the example shown in FIG. 3, the heat transfer medium supply 6 includes a plurality of third pipes 73. One of the plurality of third pipes 73 connects the first container 61 and the valve 73a to each other, and another one of the plurality of third pipes 73 connects the valve 73a and the second container 62 to each other. A position at which one of the plurality of third pipes 73 is connected to the first container 61 is a position higher than a position at which the other one of the plurality of first pipes 71 is connected to the first container 61, and may be, for example, a ceiling (or an upper wall) of the first container 61. In addition, a position at which another one of the plurality of third pipes 73 is connected to the second container 62 is a position lower than a position at which the other one of the plurality of second pipes 72 is connected to the second container 62, and may be, for example, a bottom portion of the second container 62.

At least one fourth pipe 74 is connected between the first end 55a and the first container 61. At least one fourth pipe 74 may be provided in parallel with at least one first pipe 71, or may merge with at least one first pipe 71. A position at which at least one fourth pipe 74 is connected to the first container 61 is positioned above a position at which at least one first pipe 71 is connected to the first container 61. In addition, a position at which at least one fourth pipe 74 is connected to the first container 61 is positioned below a position at which at least one third pipe 73 is connected to the first container 61. The valve 74a is connected between the first end 55a and the first container 61 via at least one fourth pipe 74. In the example shown in FIG. 3, the heat transfer medium supply 6 includes a plurality of fourth pipes 74. One of the plurality of fourth pipes 74 connects the first end 55a and the valve 74a to each other, and another one of the plurality of fourth pipes 74 connects the valve 74a and the first container 61 to each other. One of the plurality of fourth pipes 74 may merge with at least one first pipe 71 between the first end 55a and the valve 74a.

The first container 61 is configured to store the first heat transfer medium M1 therein. In one embodiment, the first container 61 may be configured to further store the second heat transfer medium M2 therein. The first container 61 is configured to change a first capacity therein. The first container 61 is configured to supply the first heat transfer medium M1 or the second heat transfer medium M2 to the flow path 55 via the at least one first pipe 71 by the decrease in the first capacity therein.

The second container 62 is configured to store a gas therein. The second container 62 may be configured to further store the second heat transfer medium M2 therein. The second container 62 is configured to change a second capacity therein. The second container 62 is configured to supply the gas to the flow path 55 via the at least one second pipe 72 by the decrease in the second capacity therein. The gas is, for example, nitrogen or a noble gas. The first container 61 and the second container 62 are configured such that the decrease in one of the first capacity and the second capacity causes an increase in the other.

In one embodiment, the first container 61 includes a side wall. The side wall of the first container 61 includes a first bellows 61a. The first container 61 is configured to change the first capacity by expansion and contraction of the first bellows 61a. Further, the second container 62 includes a side wall. The side wall of the second container 62 includes a second bellows 62a. The second container 62 is configured to change the second capacity by expansion and contraction of the second bellows 62a.

In one embodiment, the first container 61 and the second container 62 are disposed adjacent to each other along the up-down direction D1, and a direction in which the first bellows 61a expands and contracts and a direction in which the second bellows 62a expands and contracts are along the up-down direction D1. In one example, the first container 61 is disposed below the second container 62, and the second container 62 is disposed above the first container 61. In one embodiment, the first container 61 and the second container 62 include a partition wall 63 disposed between the first bellows and the second bellows. The partition wall 63 includes an upper wall of the first container 61 and a bottom wall of the second container 62. In the example shown in FIG. 3, the first container 61 and the second container 62 are separated by a single partition wall 63. The partition wall 63 may define the first container 61 together with the first bellows 61a. The partition wall 63 may define the second container 62 together with the second bellows 62a.

In one embodiment, the partition wall 63 is configured to move along the up-down direction D1. Further, the valve 73a may be configured to move together with the partition wall 63. Furthermore, at least one third pipe 73 may also be configured to move together with the partition wall 63. The upward movement of the partition wall 63 causes an increase in a first capacity and a decrease in a second capacity by expanding the first bellows and contracting the second bellows. The downward movement of the partition wall 63 causes a decrease in the first capacity and an increase in the second capacity by contracting the first bellows and expanding the second bellows.

In one embodiment, at least one of the inner surface of the first container 61, the inner surfaces of the plurality of first pipes 71, and the inner surface of the flow path 55 may include resin or ceramic. In this case, the embrittlement of each inner surface due to the liquid metal is inhibited. In one embodiment, at least one of the inner surface of the second container 62, the inner surfaces of the plurality of second pipes 72, and the inner surfaces of at least one third pipe 73 may include resin or ceramic. In this case, the embrittlement of each inner surface due to the liquid metal is inhibited.

Since the first container 61 is disposed below the second container 62, in a case where the valve 73a is opened, the first heat transfer medium M1 and the second heat transfer medium M2 stored in the second container 62 are recovered in the first container 61 via at least one third pipe 73.

In one embodiment, the substrate support assembly 11 may further include a driver 8. The driver 8 is configured to move the partition wall 63 along the up-down direction D1. The driver 8 moves the partition wall 63 along the up-down direction D1 to cause the increase in one of the first capacity and the second capacity and the decrease in the other.

In one embodiment, the partition wall 63 may include a peripheral portion 63a that protrudes outward relative to the side wall of the first container 61 in a direction intersecting the up-down direction D1. The driver 8 may include an actuator 80 and a joint 81. The actuator 80 may expand and contract along the up-down direction D1, such as an air cylinder or a hydraulic cylinder. In one example, the actuator 80 is an air cylinder. The joint 81 connects the peripheral portion 63a and the actuator 80.

In one embodiment, the actuator 80 may be disposed below the base material 10c. That is, the actuator 80 may be disposed outside the chamber 10. In the example shown in FIG. 3, the actuator 80 is fixed to the lower surface of the base material 10c via a connection member 10d.

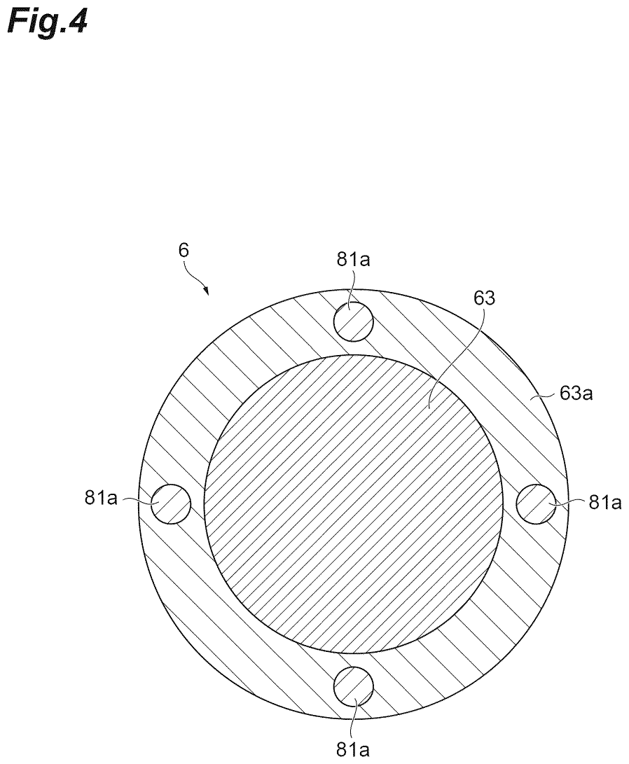

FIG. 4 is a cross-sectional view of the partition wall according to one exemplary embodiment. The joint 81 may include a plurality of shafts 81a. The plurality of shafts 81a are connected to the peripheral portion 63a. In the example shown in FIG. 4, the number of plurality of shafts 81a is four. The plurality of shafts 81a are arranged at equal intervals along the circumferential direction. The base material 10c is provided with a plurality of through-holes 10h. Each of the plurality of shafts 81a connects the actuator 80 and the peripheral portion 63a to each other through a respective one of the plurality of through-holes 10h.

In a case where there is no first heat transfer medium M1 in the flow path 55, the thermal resistance between the base 50 (second base 53) and the substrate support 51 is large. Therefore, the temperature of the substrate support 51 can be adjusted to a temperature apart from the temperature of the base 50. As a result, the temperature of the substrate W on the substrate support 51 is adjusted in a relatively high temperature range. In a case where there is the first heat transfer medium M1 in the flow path 55, the thermal resistance between the base 50 and the substrate support 51 is small. Therefore, the temperature of the substrate support 51 can be adjusted to a temperature close to the temperature of the base 50. As a result, the temperature of the substrate W on the substrate support 51 is adjusted in a relatively low temperature range. In the substrate support assembly 11, the first heat transfer medium M1 is supplied to the flow path 55, and the first heat transfer medium M1 is further collected from the flow path 55, so that the substrate temperature controllability of the substrate support assembly 11 is excellent.

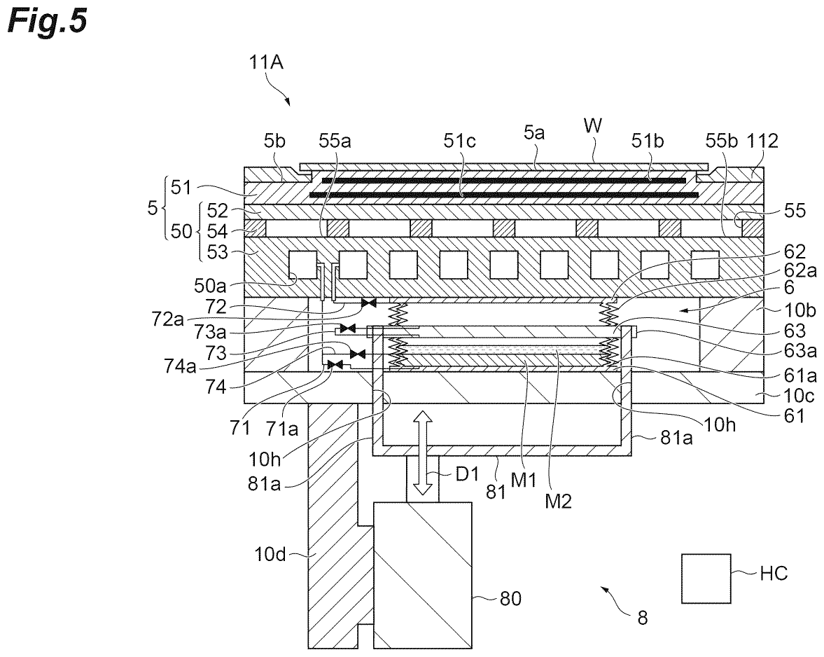

Hereinafter, a substrate support assembly according to another exemplary embodiment will be described with reference to FIG. 5. FIG. 5 is a cross-sectional view of the substrate support assembly according to another exemplary embodiment. A substrate support assembly 11A shown in FIG. 5 can be adopted instead of the substrate support assembly 11 in the plasma processing apparatus 1. Hereinafter, the substrate support assembly 11A will be described in terms of differences from the substrate support assembly 11.

In the substrate support assembly 11A, the flow path 50a is a flow path for at least one heat transfer medium. The flow path 55 may be a flow path for the other heat transfer medium different from at least one heat transfer medium. At least one first pipe 71 is connected between a first end of the flow path 50a and the first container 61. At least one second pipe 72 is connected between a second end of the flow path 50a and the second container 62. The second end of the flow path 50a is an end on a side opposite to the first end of the flow path 50a. The substrate support assembly 11A may further include a chiller unit. The chiller unit may be connected to the flow path 55 to supply the other heat transfer medium to the flow path 55. For example, the chiller unit is connected to each of the first end 55a and the second end 55b.

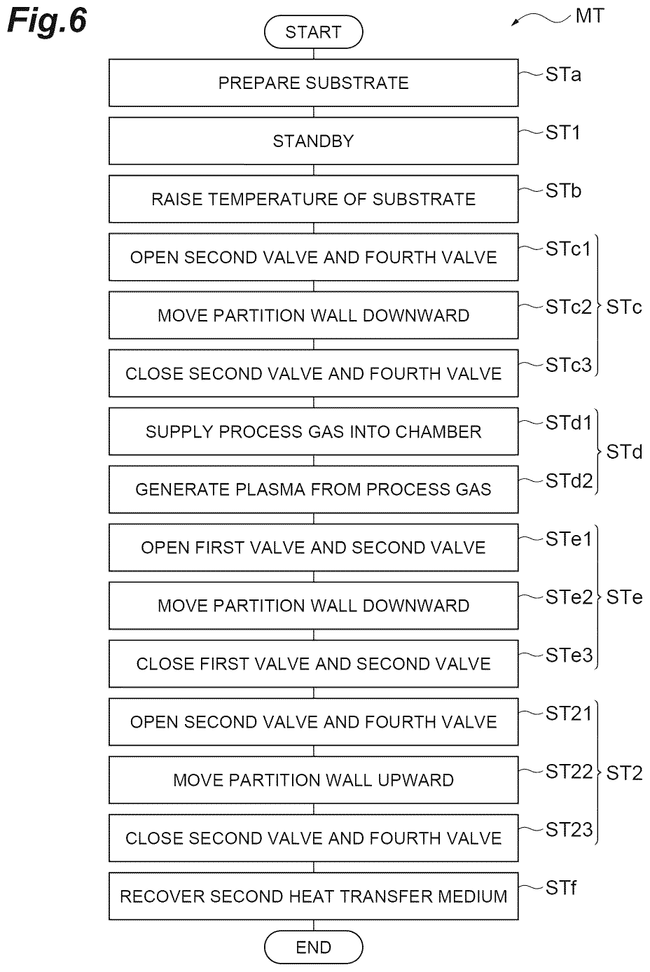

Hereinafter, a substrate processing method according to one exemplary embodiment will be described with reference to FIG. 6. FIG. 6 is a flowchart of the substrate processing method according to one exemplary embodiment. The substrate processing method (hereinafter, referred to as a “method MT”) shown in FIG. 6 may be performed by the plasma processing system shown in FIG. 1. Hereinafter, a case where the controller 2 or the operator controls each portion of the plasma processing apparatus 1 to execute the substrate processing method with respect to the substrate W will be described as an example.

The method MT includes step STa, step STb, step STc, step STd, step STe, and step STf. The method MT may include step ST1 and step ST2.

First, step STa is performed. In step STa, the substrate W is prepared on the substrate support 51 in the chamber 10 of the plasma processing apparatus 1. The steps of the method MT performed after step STa are performed in a state where the substrate W is placed on the substrate support 51.

In one embodiment, step ST1 may be performed after step STa and before step STb. In step ST1, the plasma processing apparatus 1 is in a standby state. In step ST1, the power may be supplied to the heater 51c from the power supply controlled by the heater controller HC in a state where the valves 71a, 72a, 73a, and 74a may be closed and at least the first heat transfer medium M1 and the second heat transfer medium M2 are not supplied to the flow path 55. The power supplied to the heater 51c in step ST1 may be smaller than the power supplied to the heater 51c in step STb described later. In one example, the first power may be supplied to the heater 51c. The temperature of the substrate W on the substrate support 51 may be a first temperature due to the heat generation of the heater 51c.

After step STa, step STb is performed. Step STb may be performed after step ST1. In step STb, the temperature of the substrate W prepared on the substrate support 51 is increased. Step STb includes a step of supplying the power to the heater 51c from the power supply controlled by the heater controller HC in a state where the valves 71a, 72a, 73a, and 74a are closed and at least the first heat transfer medium M1 and the second heat transfer medium M2 are not supplied to the flow path 55. The power supplied to the heater 51c in step STb may be greater than the power supplied to the heater 51c in step ST1. In one example, the second power may be supplied to the heater 51c. The second power is greater than the first power. The substrate W on the substrate support 51 may be heated to a second temperature as a target due to the heat generation of the heater 51c. The second temperature is higher than the first temperature.

In step STb, since at least the first heat transfer medium M1 and the second heat transfer medium M2 are not present in the flow path 55, the thermal resistance between the base 50 (second base 53) and the substrate support 51 is large. Therefore, the temperature of the substrate support 51 can be adjusted to a temperature apart from the temperature of the base 50. As a result, the temperature of the substrate W on the substrate support 51 is adjusted in a relatively high temperature range.

After step STb, step STc is performed. In step STc, the temperature of the substrate W disposed on the substrate support 51 is adjusted. The temperature to which the temperature of the substrate W is adjusted is a temperature for the substrate processing on the substrate W. Step STc includes step STc1, step STc2, and step STc3. Step STc includes a step of supplying power smaller than the power in step STb from the power supply controlled by the heater controller HC to the heater 51c. In one example, the temperature of the substrate W on the substrate support 51 may be maintained at the second temperature by the heat generation of the heater 51c.

In step STc1, step STc2, and step STc3, step STc1 is performed first. In step STc1, the valve 72a and the valve 74a are opened. After step STc1, step STc2 is performed. In step STc2, the partition wall 63 is moved downward by the driver 8. The partition wall 63 is moved downward, so that the second heat transfer medium M2 in the first container 61 is supplied to the flow path 55 via at least one fourth pipe 74. After step STc2, step STc3 is performed. In step STc3, the valve 72a and the valve 74a are closed. In step STc3, the second heat transfer medium M2 is held in the flow path 55.

After step STc, step STd is performed. In step STd, the substrate processing is performed on the substrate W disposed on the substrate support 51. In one example, the plasma processing may be performed in step STd. Step STd includes step STd1 and step STd2. Step STd includes a step of supplying power smaller than the power in step STb to the heater 51c from the power supply controlled by the heater controller HC. In one example, the temperature of the substrate W on the substrate support 51 may be maintained at the second temperature by the heat generation of the heater 51c.

In step STd1 and step STd2, step STd1 is performed first. In step STd1, the process gas is supplied into the chamber 10 from the gas introducer (for example, the showerhead 13). After step STd1, step STd2 is performed. In step STd2, the plasma generator 12 generates the plasma from the process gas in the chamber 10.

After step STd, step STe is performed. In step STe, the first heat transfer medium M1 is supplied to the flow path 55. In step STe, the temperature of the substrate W disposed on the substrate support 51 is lowered. Step STe includes step STe1, step STe2, and step STe3 in order to supply the first heat transfer medium M1 to the flow path 55.

In step STe1, step STe2, and step STe3, step STe1 is performed first. In step STe1, the valve 71a and the valve 72a are opened. After step STe1, step STe2 is performed. In step STe2, the partition wall 63 is moved downward by the driver 8. The partition wall 63 is moved downward, so that the first heat transfer medium M1 in the first container 61 is supplied to the flow path 55 via at least one first pipe 71. By supplying the first heat transfer medium M1 to the flow path 55, the second heat transfer medium M2 in the flow path 55 can be recovered into the second container 62. After step STe2, step STe3 is performed. In step STe3, the valve 71a and the valve 72a are closed. In step STe3, the first heat transfer medium M1 is held in the flow path 55.

In step STe, since the first heat transfer medium M1 is present in the flow path 55, the thermal resistance between the base 50 and the substrate support 51 is small. Therefore, the temperature of the substrate support 51 can be adjusted to a temperature close to the temperature of the base 50. As a result, the temperature of the substrate W on the substrate support 51 is adjusted in a relatively low temperature range.

In one embodiment, step ST2 may be performed after step STe and before step STf. Step ST2 includes step ST21, step ST22, and step ST23.

In step ST21, step ST22, and step ST23, step ST21 is performed first. In step ST21, the valve 72a and the valve 74a are opened. In step ST21, the valve 71a may be further opened. After step ST21, step ST22 is performed. In step ST22, the partition wall 63 is moved upward by the driver 8. By moving the partition wall 63 upward, the gas in the second container 62 is supplied to the flow path 55 via at least one second pipe 72. The first heat transfer medium M1 in the flow path 55 can be recovered in the first container 61 via at least one fourth pipe 74. The first heat transfer medium M1 in the flow path 55 may be recovered in the first container 61 via at least one first pipe 71. After step ST22, step ST23 is performed. In step ST23, the valve 74a and the valve 72a are closed.

After step STe, step STf is performed. Step STf may be performed after step ST2. In step STf, at least the second heat transfer medium M2 is recovered from the second container 62 to the first container 61. In step STf, the first heat transfer medium M1 and the second heat transfer medium M2 may be recovered from the second container 62 to the first container 61. Step STf includes a step of opening the valve 73a in a state where the valve 71a, the valve 72a, and the valve 74a are closed and the partition wall 63 is moved upward. The second heat transfer medium M2 is recovered from the second container 62 to the first container 61 via at least one third pipe 73.

Although various exemplary embodiments have been described above, various additions, omissions, substitutions, and modifications may be made without being limited to the exemplary embodiments described above. In addition, other embodiments can be formed by combining elements in different embodiments.

The first container 61 need not include the first bellows 61a. The second container 62 need not include the second bellows 62a. Each of the first container 61 and the second container 62 may be configured with a cylinder and a piston. Each piston is configured to change the volume of each cylinder. The driver 8 may be configured to operate the piston of each of the first container 61 and the second container 62. The first container 61 and the second container 62 may be configured with a single cylinder and the partition wall 63. In this case, the partition wall 63 is configured to slide in a single cylinder. The partition wall 63 is used as a piston in the cylinder, and is configured to change the volume of each of the first container 61 and the second container 62.

The flow path 55 may include a plurality of flow paths independent of each other. In one example, the flow path 55 may include a first flow path positioned below the central region 5a (substrate support surface) and a second flow path positioned below the annular region 5b (ring support surface).

In the method MT, all of steps STa to STf need not be performed. In one example, in the method MT, some of steps STa to STf may be skipped.

Here, the various exemplary embodiments included in the present disclosure are described in the following [E1] to [E16].
[E1] 1. A substrate support assembly comprising:
a base including a flow path;
a substrate support on the base; and
a heat transfer medium supply connected to the flow path,
wherein
the heat transfer medium supply includes
   a first container configured to store therein a heat transfer medium,
   at least one first pipe connected between a first end of the flow path and the first container,
   a second container configured to store a gas, wherein a specific gravity of the heat transfer medium is greater than a specific gravity of the gas,
   at least one second pipe connected between a second end of the flow path and the second container,
   at least one third pipe, and
   a valve connected in series with the at least one third pipe between the first container and the second container,
the first container is configured to change therein a first capacity to supply the heat transfer medium to the flow path via the at least one first pipe by a decrease in the first capacity,
the second container is configured to change therein a second capacity to supply the gas to the flow path via the at least one second pipe by a decrease in the second capacity, and
the first container and the second container are configured to cause the decrease in one of the first capacity and the second capacity causes an increase in an other of the first capacity and the second capacity.
[E2] The substrate support assembly according to E1, wherein
the first container includes a side wall including a first bellows and is configured to change the first capacity by expansion and contraction of the first bellows, and
the second container includes a side wall including a second bellows and is configured to change the second capacity by expansion and contraction of the second bellows.
[E3] The substrate support assembly according to E2, wherein
the first container is below the second container.
[E4] The substrate support assembly according to E2 or E3, wherein
the first container and the second container include a partition wall between the first bellows and the second bellows, and
the first bellows and the second bellows are configured to expand and contract by movement of the partition wall in a vertical direction.
[E5] The substrate support assembly according to E4, wherein
the partition wall is an upper wall of the first container and a bottom wall of the second container.
[E6] The substrate support assembly according to E4 or E5, wherein
valve is configured to move together with the partition wall.
[E7] The substrate support assembly according to any one of E4 to E6, further including:
a driver configured to move the partition wall in the up-down direction.
[E8] The substrate support assembly according to E7, wherein
the partition wall includes a peripheral portion protruding outward relative to the side wall of the first container, and
the driver includes
   an actuator, and
   a joint that connects the peripheral portion and the actuator for moving the partition wall in the vertical direction.
[E9] The substrate support assembly according to E8, further including:
a base member; and
an insulator on the base member,
wherein
the base is supported on the base member via the insulator,
the heat transfer medium supply is between the base and the base member,
the actuator is below the base member,
the base member includes a plurality of through-holes below the peripheral portion,
the joint includes a plurality of shafts, and
each of the plurality of shafts is connected to the peripheral portion through a respective one of the plurality of through-holes.
[E10] The substrate support assembly according to E8 or E9, wherein
the actuator includes an air cylinder.
[E11] The substrate support assembly according to any one of E1 to E10, wherein
the heat transfer medium supply further includes a valve connected in series with the at least one first pipe between the first end and the first container.
[E12] The substrate support assembly according to any one of E1 to E11, wherein
the heat transfer medium supply further includes a valve connected in series with the at least one second pipe between the second end and the second container.
[E13] The substrate support assembly according to any one of E1 to E12, wherein
the heat transfer medium is a liquid metal.
[E14] The substrate support assembly according to any one of E1 to E13, wherein
at least one of an inner surface of the first container, an inner surface of the at least one first pipe, and an inner surface of the flow path includes resin or ceramic.
[E15] The substrate support assembly according to any one of E1 to E14, wherein
the heat transfer medium is a first heat transfer medium,
the first container is configured to store therein a second heat transfer medium, the second heat transfer medium having a specific gravity smaller than a specific gravity of the first heat transfer medium and greater than a specific gravity of the gas,
the heat transfer medium supply further includes
   at least one fourth pipe, and
   a valve connected in series with the at least one fourth pipe between the first end and the first container,
wherein a position at which the at least one fourth pipe is connected to the first container is above a position at which the at least one first pipe is connected to the first container.
[E16] A substrate processing apparatus including:
a chamber; and
the substrate support assembly according to any one of E1 to E15, configured to support a substrate in the chamber.
[E17] A substrate processing method performed in a substrate processing apparatus, the substrate processing apparatus comprising:
a chamber;
a substrate support assembly configured to support a substrate in the chamber;
a heater disposed in a substrate support of the substrate support assembly;
a heater controller electrically connected to the heater;
a gas introducer configured to introduce a process gas into the chamber; and
a plasma generator configured to generate plasma from the process gas in the chamber,
wherein
the substrate support assembly includes
   a base including a flow path,
   the substrate support on the base, and
   a heat transfer medium supply connected to the flow path, and
the heat transfer medium supply includes
   a first container including a partition wall that is an upper wall thereof and a side wall including a first bellows configured to expand and contract by movement of the partition wall in a vertical direction, configured to store therein a first heat transfer medium and a second heat transfer medium, and configured to change therein a first capacity to supply the first heat transfer medium and the second heat transfer medium to the flow path via at least one first pipe by a decrease in the first capacity,
   the at least one first pipe,
   a first valve connected in series with the at least one first pipe between a first end of the flow path and the first container,
   a second container including the partition wall that is a bottom wall thereof and a side wall including a second bellows configured to expand and contract by the movement of the partition wall in the vertical direction, configured to store a gas therein, and configured to change a second capacity therein to supply the gas to the flow path via at least one second pipe by a decrease in the second capacity, wherein a specific gravity of the second heat transfer medium is smaller than a specific gravity of the first heat transfer medium and greater than a specific gravity of the gas,
   the at least one second pipe,
   a second valve connected in series with the at least one second pipe between a second end of the flow path and the second container,
   at least one third pipe,
   a third valve connected in series with the at least one third pipe between the first container and the second container,
   at least one fourth pipe connected to the first container above a position at which the at least one first pipe is connected to the first container,
   a fourth valve connected in series with the at least one fourth pipe between the first end and the first container, and
   a driver configured to move the partition wall in the vertical direction,
the substrate processing method comprising:
preparing a substrate on the substrate support;
raising a temperature of the substrate after the preparing a substrate;
adjusting the temperature of the substrate to a temperature for substrate processing on the substrate after the raising a temperature of the substrate;
performing the substrate processing on the substrate after the raising a temperature of the substrate;
lowering the temperature of the substrate after the performing the substrate processing on the substrate; and
recovering at least the second heat transfer medium from the second container after the lowering the temperature of the substrate,
wherein the raising a temperature of the substrate includes supplying power to the heater from the heater controller in a state where the first valve, the second valve, the third valve, and the fourth valve are closed and at least the first heat transfer medium and the second heat transfer medium are not supplied to the flow path,
the adjusting the temperature of the substrate and the performing the substrate processing on the substrate include supplying power smaller than the power in the raising a temperature of the substrate to the heater from the heater controller over the adjusting the temperature of the substrate and the performing the substrate processing on the substrate,
the adjusting the temperature of the substrate includes, for supplying the second heat transfer medium to the flow path, wherein
   opening the second valve and the fourth valve,
   moving the partition wall downward by the driver after the opening the second valve and the fourth valve, and
   closing the second valve and the fourth valve after the moving the partition wall downward by the driver,
the performing the substrate processing on the substrate includes
   supplying the process gas into the chamber from the gas introducer, and
   generating plasma from the process gas in the chamber by the plasma generator,
the lowering the temperature of the substrate includes, for supplying the first heat transfer medium to the flow path,
   opening the first valve and the second valve,
   moving the partition wall downward by the driver after the opening the first valve and the second valve, and
   closing the first valve and the second valve after the moving the partition wall downward by the driver, and
the recovering at least the second heat transfer medium includes opening the third valve in a state where the first valve, the second valve, and the fourth valve are closed and the partition wall is moved upward.

From the foregoing description, it will be understood that various embodiments of the present disclosure have been described herein for purposes of illustration, and that various modifications may be made without departing from the scope and gist of the present disclosure. Accordingly, the various embodiments disclosed herein are not intended to be limiting, with the true scope and gist being indicated by the appended claims.

What is claimed is:

1. A substrate support assembly comprising:
a base including a flow path;
a substrate support on the base; and
a heat transfer medium supply connected to the flow path,
wherein
the heat transfer medium supply includes
a first container configured to store therein a heat transfer medium,
at least one first pipe connected between a first end of the flow path and the first container,
a second container configured to store a gas, wherein a specific gravity of the heat transfer medium is greater than a specific gravity of the gas,
at least one second pipe connected between a second end of the flow path and the second container,
at least one third pipe, and
a valve connected in series with the at least one third pipe between the first container and the second container,
the first container is configured to change therein a first capacity to supply the heat transfer medium to the flow path via the at least one first pipe by a decrease in the first capacity,
the second container is configured to change therein a second capacity to supply the gas to the flow path via the at least one second pipe by a decrease in the second capacity, and
the first container and the second container are configured to cause the decrease in one of the first capacity and the second capacity causes an increase in an other of the first capacity and the second capacity.

2. The substrate support assembly according to claim 1, wherein
the first container includes a side wall including a first bellows and is configured to change the first capacity by expansion and contraction of the first bellows, and
the second container includes a side wall including a second bellows and is configured to change the second capacity by expansion and contraction of the second bellows.

3. The substrate support assembly according to claim 2, wherein
the first container is below the second container.

4. The substrate support assembly according to claim 3, wherein
the first container and the second container include a partition wall between the first bellows and the second bellows, and
the first bellows and the second bellows are configured to expand and contract by movement of the partition wall in a vertical direction.

5. The substrate support assembly according to claim 4, wherein
the partition wall is an upper wall of the first container and a bottom wall of the second container.

6. The substrate support assembly according to claim 4, wherein
the valve is configured to move together with the partition wall.

7. The substrate support assembly according to claim 4, further comprising:
a driver configured to move the partition wall in the vertical direction.

8. The substrate support assembly according to claim 7, wherein
the partition wall includes a peripheral portion protruding outward relative to the side wall of the first container, and
the driver includes
an actuator, and
a joint that connects the peripheral portion and the actuator for moving the partition wall in the vertical direction.

9. The substrate support assembly according to claim 8, further comprising:
a base member; and
an insulator on the base member,
wherein
the base is supported on the base member via the insulator,
the heat transfer medium supply is between the base and the base member,
the actuator is below the base member,
the base member includes a plurality of through-holes below the peripheral portion,
the joint includes a plurality of shafts, and
each of the plurality of shafts is connected to the peripheral portion through a respective one of the plurality of through-holes.

10. The substrate support assembly according to claim 8, wherein
the actuator includes an air cylinder.

11. The substrate support assembly according to claim 1, wherein
the heat transfer medium supply further includes a valve connected in series with the at least one first pipe between the first end and the first container.

12. The substrate support assembly according to claim 1, wherein
the heat transfer medium supply further includes a valve connected in series with the at least one second pipe between the second end and the second container.

13. The substrate support assembly according to claim 1, wherein
the heat transfer medium is a liquid metal.

14. The substrate support assembly according to claim 13, wherein
at least one of an inner surface of the first container, an inner surface of the at least one first pipe, and an inner surface of the flow path includes resin or ceramic.

15. The substrate support assembly according to claim 3, wherein
the heat transfer medium is a first heat transfer medium,
the first container is configured to store therein a second heat transfer medium, the second heat transfer medium having a specific gravity smaller than a specific gravity of the first heat transfer medium and greater than a specific gravity of the gas,
the heat transfer medium supply further includes
at least one fourth pipe, and
a valve connected in series with the at least one fourth pipe between the first end and the first container,
wherein a position at which the at least one fourth pipe is connected to the first container is above a position at which the at least one first pipe is connected to the first container.

16. A substrate processing apparatus comprising:
a chamber; and
the substrate support assembly according to claim 1, configured to support a substrate in the chamber.

17. A substrate processing method performed in a substrate processing apparatus, the substrate processing apparatus comprising:
a chamber;
a substrate support assembly configured to support a substrate in the chamber;
a heater disposed in a substrate support of the substrate support assembly;
a heater controller electrically connected to the heater;
a gas introducer configured to introduce a process gas into the chamber; and
a plasma generator configured to generate plasma from the process gas in the chamber,
wherein
the substrate support assembly includes
a base including a flow path,
the substrate support on the base, and
a heat transfer medium supply connected to the flow path, and
the heat transfer medium supply includes
a first container including a partition wall that is an upper wall thereof and a side wall including a first bellows configured to expand and contract by movement of the partition wall in a vertical direction, configured to store therein a first heat transfer medium and a second heat transfer medium, and configured to change therein a first capacity to supply the first heat transfer medium and the second heat transfer medium to the flow path via at least one first pipe by a decrease in the first capacity,
the at least one first pipe,
a first valve connected in series with the at least one first pipe between a first end of the flow path and the first container,
a second container including the partition wall that is a bottom wall thereof and a side wall including a second bellows configured to expand and contract by the movement of the partition wall in the vertical direction, configured to store a gas therein, and configured to change a second capacity therein to supply the gas to the flow path via at least one second pipe by a decrease in the second capacity, wherein a specific gravity of the second heat transfer medium is smaller than a specific gravity of the first heat transfer medium and greater than a specific gravity of the gas,
the at least one second pipe,
a second valve connected in series with the at least one second pipe between a second end of the flow path and the second container,
at least one third pipe,
a third valve connected in series with the at least one third pipe between the first container and the second container,
at least one fourth pipe connected to the first container above a position at which the at least one first pipe is connected to the first container,
a fourth valve connected in series with the at least one fourth pipe between the first end and the first container, and
a driver configured to move the partition wall in the vertical direction,
the substrate processing method comprising:
preparing a substrate on the substrate support;
raising a temperature of the substrate after the preparing a substrate;
adjusting the temperature of the substrate to a temperature for substrate processing on the substrate after the raising a temperature of the substrate;
performing the substrate processing on the substrate after the raising a temperature of the substrate;
lowering the temperature of the substrate after the performing the substrate processing on the substrate; and
recovering at least the second heat transfer medium from the second container after the lowering the temperature of the substrate,
wherein the raising a temperature of the substrate includes supplying power to the heater from the heater controller in a state where the first valve, the second valve, the third valve, and the fourth valve are closed and at least the first heat transfer medium and the second heat transfer medium are not supplied to the flow path,
the adjusting the temperature of the substrate and the performing the substrate processing on the substrate include supplying power smaller than the power in the raising a temperature of the substrate to the heater from the heater controller over the adjusting the temperature of the substrate and the performing the substrate processing on the substrate,
the adjusting the temperature of the substrate includes, for supplying the second heat transfer medium to the flow path, wherein
opening the second valve and the fourth valve,
moving the partition wall downward by the driver after the opening the second valve and the fourth valve, and
closing the second valve and the fourth valve after the moving the partition wall downward by the driver,
the performing the substrate processing on the substrate includes
supplying the process gas into the chamber from the gas introducer, and
generating plasma from the process gas in the chamber by the plasma generator,
the lowering the temperature of the substrate includes, for supplying the first heat transfer medium to the flow path,
opening the first valve and the second valve,
moving the partition wall downward by the driver after the opening the first valve and the second valve, and
closing the first valve and the second valve after the moving the partition wall downward by the driver, and
the recovering at least the second heat transfer medium includes opening the third valve in a state where the first valve, the second valve, and the fourth valve are closed and the partition wall is moved upward.
